(19) United States
(12) Patent Application Publication
(10) Pub. No.: US 2025/0309833 A1
(43) Pub. Date: Oct. 2, 2025

(54) WIDEBAND DOHERTY POWER AMPLIFIER WITH DEVICE PARASITIC COMPENSATION AND IMPEDANCE INVERSION

(71) Applicants: Wipro Limited, Bangalore (IN); Indian Institute of Technology Roorkee, Roorkee (IN)

(72) Inventors: Dushyant Kumar SHARMA, Bengaluru (IN); Karun RAWAT, Roorkee (IN); Mohammad Abdul SHUKOOR, Roorkee (IN); Ahmad Zakaria AHMAD, Roorkee (IN)

(73) Assignees: Wipro Limited, Bangalore (IN); Indian Institute of Technology Roorkee, Roorkee (IN)

(21) Appl. No.: 18/677,046

(22) Filed: May 29, 2024

(30) Foreign Application Priority Data
Mar. 29, 2024 (IN) 202341082863

(51) Int. Cl. H03F 1/02; H03F 1/56; H03F 3/24

(52) U.S. Cl. CPC H03F 1/0288; H03F 1/56; H03F 3/245; H03F 2200/222

(57) ABSTRACT

Disclosed herein is a wideband Doherty Power Amplifier (DPA) circuit. The wideband DPA circuit comprises a main PA, an auxiliary PA, and an input power splitter configured to split input power into main PA and auxiliary PA. Further, the circuit comprises a multi-phasing block component to provide phase difference between the main PA and the auxiliary PA. Furthermore, the circuit comprises a parasitic compensator & impedance inverter connected to the main PA to compensate a parasitic load on the main PA and modulate load in the DPA. Also, the circuit comprises a parasitic canceller connected to the auxiliary PA to compensate for the parasitic load on the auxiliary PA and avoid leakage of current from the main PA to the auxiliary PA, when the auxiliary PA is in an ‘OFF’ state. Additionally, the circuit comprises an output impedance transformer connected to the main PA and the auxiliary PA.

### TECHNICAL FIELD

The present disclosure, in general, relates to power amplifiers, and more specifically, to a wideband Doherty power amplifier with device parasitic compensation and impedance inversion.

### BACKGROUND

In wireless communication, advanced modulation techniques such as Quadrature Amplitude Modulation (QAM) and Orthogonal Frequency Division Multiplexing (OFDM) have been widely employed to achieve high data rate and spectrum efficiency. To achieve spectrum efficiency, front-end Power Amplifier (PA) must operate significantly below its saturation to prevent signal distortion (non-linearity), since the transmitted signal has a high Peak-to-Average-Power Ratio (PAPR). However, traditional PA architectures, such as class B/C, often suffer from poor efficiency when operating at significant Output Back-Off (OPBO). Consequently, the conventional PAs lead to an increase in Operating Expenditures (OPEX) of the wireless network, as they play a vital role in determining overall wireless link performance.

Various topologies have been proposed recently for enhancing the efficiency of the PAs. Some of these topologies include Envelope Tracking, Dynamic Load Modulation (DLM), Doherty Power Amplifier (DPA), and Envelope Elimination and Restoration. Among these, DPA is one of the frequently used topologies in commercial wireless systems, since it is a fully analogue architecture that amplifies complex and modulated signals efficiently over an extensive dynamic range and handles high PAPR signals.

FIG. 1 illustrates circuit diagram of a conventional DPA 100, which includes an input power splitter 101, which splits the input power across a main PA 103 path and an auxiliary PA 105 path. In an example, the main PA 103 is biased (i.e., gate voltage value setting) at its pinch-off threshold or at a value which is slightly above the pinch off threshold. This ensures that the main PA 103 operates at low power levels. On the other hand, the auxiliary PA 105 is biased well below the pinch-off threshold, which enables the auxiliary PA 105 to operate only when input power drive is high and crosses a certain a threshold value. The main PA 103 includes an input offset line 1 107₁, an input matching network 1 109₁, a transistor 1 (Q1) 110₁, an output matching network 1 111₁, and a quarter wave transformer 113₁. The auxiliary PA 105 includes an input offset line 2 107₂, an input matching network 2 109₂, a transistor 2 (Q2) 110₂, an output matching network 2 111₂, and a phase-offset line 115. Further, a quarter wave transformer 2 113₂ is placed at junction ‘J’, where the main PA 103 and the auxiliary PA 105 are connected.

By operation, in the conventional DPA 100, at low power level, only the main PA 103 operates, while reaching a maximum voltage (i.e., voltage saturation) even at the low output current. At a certain back-off, when the output voltage of the main PA 103 reaches its saturation value, the auxiliary PA 105 starts operating and gradually contributes to the output current, thereby reducing the load on the main PA 103. Therefore, the load seen by the main PA 103 reduces, whereas the output current still increases, thereby keeping the output voltage of the main PA 103 constant at its saturation value. In other words, the main PA 103 operates at a voltage saturation even at the back-off power, and thereby endures high efficiency. The auxiliary PA 105 starts contributing an additional current after the back-off, thereby keeping the main PA 103 operating at a saturation value, beyond the back-off region, till the auxiliary PA 105 reaches its saturation. Thus, the conventional DPA 100 has good efficiency from back-off to the peak value, where both the main PA 103 and the auxiliary PA 105 reach their saturation, resulting into dynamic range of input power level for which the DPA 100 operates in high efficiency region.

Additionally, in the conventional DPA 100, the transistor Q1 110₁ of the main PA 103 and the transistor Q2 110₂ of the auxiliary PA 105 are matched to their optimum loads using the output matching networks 111₁ and 111₂. Due to load modulation, the output of the matching network 111₁ also varies as the main PA 103 and the auxiliary PA 105 interact through their currents. In other words, load modulation occurs due to interaction between the main PA 103 and the auxiliary PA 105 through their currents. Therefore, the matching network 111₁ must ensure that, at different values of the input power drive, an optimum load is always presented to the transistor Q1 110₁ even when the terminating loads of the output matching network 111₁ are varying due to the load modulation. This requirement makes it difficult for the matching logic implemented on the conventional DPA 100 to cover a wide bandwidth and wide dynamic range of input power drive during an actual operation of the DPA.

Additionally, the quarter wave transformer 1 113₁ on the main PA 103 is used to provide an impedance inversion from inherent low impedance (i.e., R₀/2 seen by the main PA 103 towards junction ‘J’) to the required high impedance value (2R₀) seen by the output matching network 111₁ of the main PA 103 at back-off. This is required for the main PA 103 to operate in saturation region at back-off power level, to achieve the desired high efficiency at low power region. However, due to impedance transformation introduced by the quarter wave transformer 1 113₁, an additional phase shift of 90° must be added at the output of the main PA 103. To compensate for this additional phase shift, a phase offset of 90° must be added at the input offset line 2 107₂ of the auxiliary PA 105.

Moreover, in the auxiliary PA 105, the phase-offset line 115 must be designed to ensure that no current leaks from the main PA 103 to the auxiliary PA 105, when the auxiliary PA 105 is in ‘OFF’ condition. The leakage may occur due to parasitic load of the device used in the auxiliary PA 105 and the output matching network 111₂, which presents a non-open circuit impedance. Therefore, on the conventional DPA 100, the phase-offset line 115 must be configured to transform the non-open circuit impedance to the open circuit at junction ‘J’, so that the main PA 103 current does not leak to the auxiliary PA 105. However, the introduction of the phase-offset line 115 adds an additional phase offset at the output of the auxiliary PA 105. In order to compensate for this additional phase offset, the input offset line 1 107₁ must be used in the main PA 103 to provide the same phase offset. Since the load at the terminating junction ‘J’ is R₀/2 (where R₀ is typically 50Ω), an additional quarter wave transformer, i.e., quarter wave transformer 2 113₂ must be used to transform the standard 50Ω load to the required load at the junction ‘J’.

Due to the need to compensate various additional phase shifts, as explained above, the conventional DPA 100 suffers from numerous limitations. One of the main limitations is that the conventional DPA 100 is limited only to narrowband operation due to the narrow band impedance inversion by the quarter wave transformer 1 113₁ and the quarter wave transformer 2 113₂. Even if the input matching network 1 109₁ and the output matching network 111₁ on the main PA 103, as well as the input matching network 2 109₂ and the output matching network 111₂ on the auxiliary PA 105 are broadband, the impedance inversion by the quarter wave transformer 1 113₁ still limits the performance. Also, though the conventional matching networks can match the standard load R₀ (usually 50Ω) to the required optimum load impedance Rₒₚₜ at transistor intrinsic current generator reference plane over a wide bandwidth, ensuring the application of the Rₒₚₜ becomes uncertain when the standard load R₀ undergoes changes with the input drive due to load modulation. Moreover, the conventional DPA 100 exhibits leakage of the current from the main PA 103 to the auxiliary PA 105, when the auxiliary PA 105 is in the ‘OFF’ state. This reduces the efficiency and gain of the DPA at low power operation. The leakage may be reduced by the phase-offset line 115, but only in a narrow band region. Consequently, the loads required in the conventional DPA 100 cannot guarantee a nonlinear compensation.

Furthermore, in the conventional DPA 100, the matching networks of the main PA 103 and the auxiliary PA 105 are designed independently without considering the overall device parasitic of the DPA 100. For example, the output matching network 2 111₂ of the auxiliary PA 105 is designed considering its operation only at the saturation point. Since the parasitic of the auxiliary PA 105 and the output matching network 2 111₂ are not considered, it becomes challenging to obtain a required load presented to the main PA 103 at back-off. This once again results into leakage of current from the main PA 103 towards the auxiliary PA 105 at back-off, when the auxiliary transistor is in ‘OFF’ condition. Though these variations are minimal and can be disregarded, however, in devices of different sizes, where parasitic effects are more significant, such variations are not negligible and cannot be ignored. Consequently, it is also essential to design the matching network and the impedance inversion as an integrated unit, considering the overall device parasitic of the DPA.

The information disclosed in this background of the disclosure section is only for enhancement of understanding of the general background of the invention and should not be taken as an acknowledgement or any form of suggestion that this information forms the prior art already known to a person skilled in the art.

### SUMMARY

The present disclosure discloses a wideband Doherty Power Amplifier (DPA) circuit. The wideband DPA circuit comprises a main PA, an auxiliary PA, and an input power splitter configured to split input power into main PA and auxiliary PA. Further, the circuit comprises a multi-phasing block component to provide phase difference between the main PA and the auxiliary PA. Furthermore, the circuit comprises a parasitic compensator & impedance inverter connected to the main PA to compensate a parasitic load on the main PA and modulate load in the DPA. Also, the circuit comprises a parasitic canceller connected to the auxiliary PA to compensate for the parasitic load on the auxiliary PA and avoid leakage of current from the main PA to the auxiliary PA, when the auxiliary PA is in an ‘OFF’ state. Additionally, the circuit comprises an output impedance transformer connected to the main PA and the auxiliary PA.

In an embodiment of the present disclosure, the parasitic compensator & impedance inverter is designed based on parasitic of one or more transistors connected to the main PA, an impedance Z_{L} provided by the output impedance transformer and a quasi-open circuit impedance provided by the parasitic canceller, such that the parasitic compensator & impedance inverter provides a required load modulation over a large variation in the input power and wide bandwidth.

In an embodiment of the present disclosure, the parasitic compensator & impedance inverter is configured with a plurality of sections, each section comprising a transmission line and a shunt admittance. The number of sections in the parasitic compensator & impedance inverter is determined based on frequency of operation of the circuit, optimum load for transistor and corresponding parasitic of the transistor.

In an embodiment of the present disclosure, the parasitic canceller provides cancellation of the parasitic load presented by an auxiliary transistor in the auxiliary PA based on the parasitic load presented by the one or more transistors on the main PA. Also, the parasitic canceller is configured with a plurality of sections, each section comprising a transmission line and a shunt admittance. The number of sections in the parasitic canceller is determined based on frequency of operation of the circuit, optimum load for transistor and corresponding parasitic of the transistor.

In an embodiment of the present disclosure, the transmission line on each of the plurality of sections has a characteristic impedance corresponding to each of the plurality of sections. Further, an admittance value of the shunt admittance is realized using at least one inductor in the circuit, at least one capacitor in the circuit, a series combination of the at least one inductor and the at least one capacitor or a shunt combination of the at least one inductor and the at least one capacitor. The admittance value of the shunt admittance is realized using a transmission line stub with a predefined characteristic impedance value.

In an embodiment of the present disclosure, the multi-phasing block component is configured with a combination of delay lines to provide multiple phase shifts corresponding to different values of a frequency of operation to compensate a phase difference between the main PA and the auxiliary PA.

In an embodiment of the present disclosure, operation of the auxiliary PA is triggered when an output voltage of the main PA is more than a predefined peak voltage. An output current generated during the operation of the auxiliary PA causes modulation of the load on the main PA such that the load on the main PA reduces with increase in the input power. The network parameters of the circuit are obtained simultaneously over the wide bandwidth, while considering their effect on each other and the effect of load impedance ZL provided by the output impedance transformer. Also, the circuit may be configured to modify the load to the one or more transistors in the main PA over a wide input drive and wide bandwidth while avoiding clipping and corresponding addition of nonlinearity in operation of the DPA.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 illustrates architecture of a conventional Doherty Power Amplifier (DPA);

FIG. 2 illustrates an exemplary architecture of the proposed Doherty Power Amplifier (DPA), in accordance with various embodiments of the present disclosure;

FIG. 3 illustrates a detailed architecture of the proposed DPA, in accordance with various embodiments of the present disclosure;

FIG. 4 illustrates an exemplary internal architecture of a parasitic compensator & impedance inverter of the proposed DPA, in accordance with an embodiment of the present disclosure;

FIG. 5 illustrates an exemplary internal architecture of a parasitic canceller of the proposed DPA, in accordance with an embodiment of the present disclosure;

FIG. 6 illustrates an exemplary architecture of an output impedance transformer of the proposed DPA, in accordance with an embodiment of the present disclosure;

FIG. 7A illustrates simulation of drain efficiency of the proposed DPA with normalized input voltage drive, in accordance with an embodiment of the present disclosure; and

FIG. 7B illustrates simulation of drain efficiency in the proposed DPA with normalized frequency, in accordance with an embodiment of the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

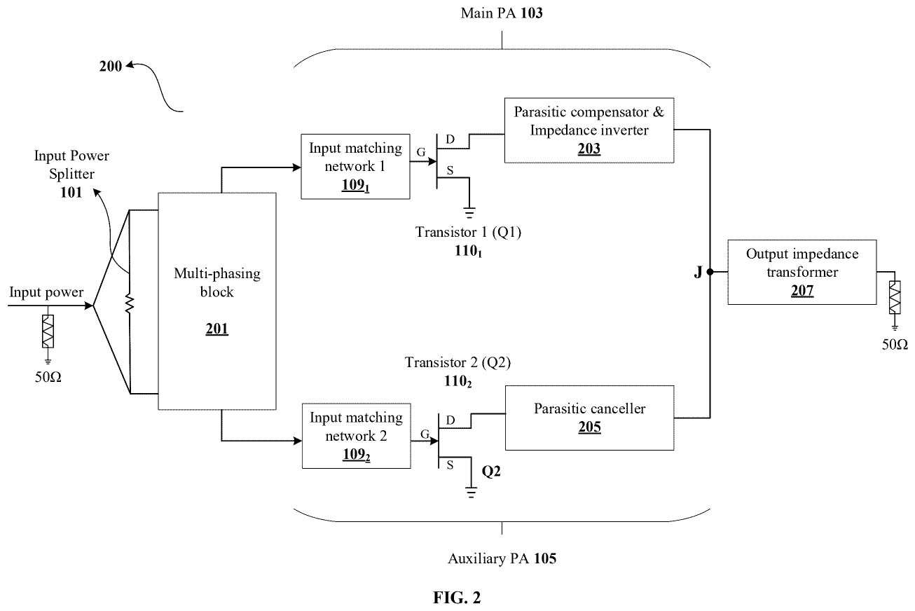

The present disclosure relates to a wideband Doherty Power Amplifier (DPA) with device parasitic compensation and impedance inversion. In an embodiment, the proposed wideband DPA performs wideband compensation for impedance inversion, matching of main Power Amplifier (PA) and auxilary PA and parasitic cancellation for optimal operation of the DPA. Consequently, the proposed wideband DPA aims to rectify one or more imperfections such as, leakage of current from the main PA to the auxiliary PA when the auxiliary PA is in an ‘OFF’ condition, providing optimum load impedance and so on. In other words, in the proposed wideband DPA, the matching network and the impedance inversion is integrated into a single unit, which facilitates: (1) proper impedance matching between the main PA and the auxiliary PA; (2) proper load modulation and optimal load conditions for both main PA and the auxiliary PA; and (3) reduced distortion and improved linearity of the DPA. The structure and internal architecture of the proposed wideband DPA is explained in detail with reference to FIGS. 2-7 in the following paragraphs.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

FIG. 2 illustrates an exemplary architecture of the proposed Doherty Power Amplifier (DPA) 200, which may be used to provide a frequency agile power amplification. In an embodiment, the DPA 200 may comprise, without limitation, an input power splitter 101, a multi-phasing block 201, a main Power Amplifier (PA) 103 path, an auxiliary PA 105 path and an output impedance transformer 207. In an embodiment, the main PA 103 may further comprise, without limiting to, an input matching network 1 109₁, a transistor 1 Q1 110₁ and a parasitic compensator & impedance inverter 203. The auxiliary PA 105 may comprise, without limiting to, an input matching network 2 109₂, a transistor 2 Q2 110₂ and a parasitic canceller 205.

In an embodiment, the input power splitter 101 may be used to divide an input power across the main PA 103 and the auxiliary PA 105 and transmit the split input power to the multi-phasing block 201. In an embodiment, the operation of the the auxiliary PA 105 may be triggered only when an output voltage of the main PA 103 is more than a predefined peak voltage.

In an embodiment, the multi-phasing block 201 may be configured to provide multiple phase shifts to different values of the input power. The multi-phasing block 201 may be comprised of a combination of multiple delay lines, which can provide a required phase shift to the main PA 103, relative to the auxiliary PA 105. That is, the multi-phasing block 201 ensures that desired phase shifts are provided to different values of the input power. Consequently, the multi-phasing block 201 compensates for the phase difference between the main PA 103 and the auxiliary PA 105, which primarily occurs due to the phase difference between the parasitic compensator & impedance inverter 203 and parasitic canceller 205, and the input matching network 1 109₁, and input matching network 2 109₂. Additionally, the multi-phasing block 201 may be also configured to compensate for the phase disparity between the main PA 103 and the auxiliary PA 105. In such a case, the input to the main PA 103 may be shifted by a factor of ‘e^{jϕ}’, where the input to the auxiliary PA 105 will be shifted by a relative 0° phase. This difference between phases added to the main PA 103 and the auxiliary PA 105 ensures appropriate load modulation in the proposed wideband DPA 200.

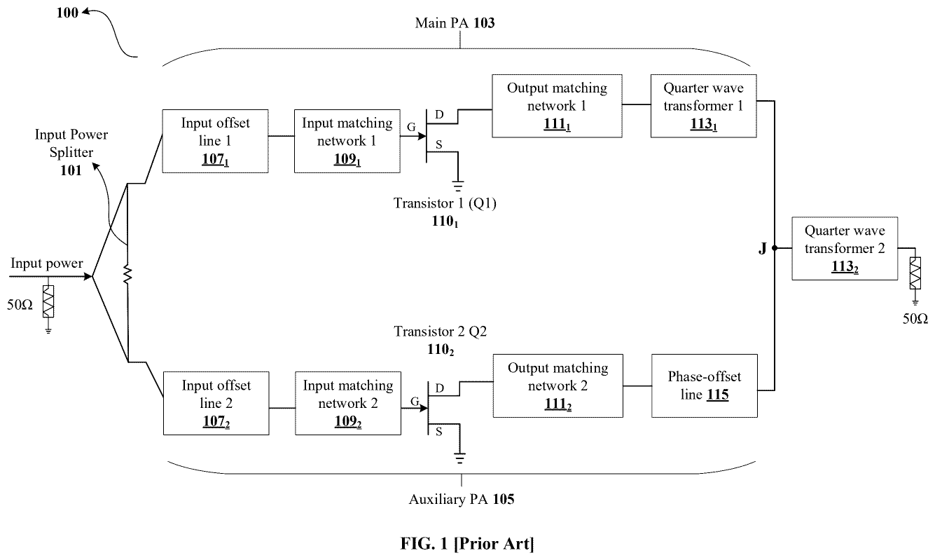

In an embodiment, the input matching network 1 109₁ on the main PA 103 and the input matching network 2 109₂ on the auxiliary PA 105 may be configured to match the inputs of the main PA 103 and the auxiliary PA 105, respectively. In an embodiment, the operation and functionality of the input matching network 1 109₁ and the input matching network 2 109₂ may be same as the input matching networks on the conventional DPA 100, discussed with reference to FIG. 1 of the present disclosure.

The transistor 1 Q1 110₁ and the transistor 2 Q2 110₂ represent the parasitic load on the main PA 103 and the auxiliary PA 105 respectively. Both the transistor 1 Q1 110₁ and the transistor 2 Q2 110₂ may be an electrical manifestation of physical geometry of the transistors.

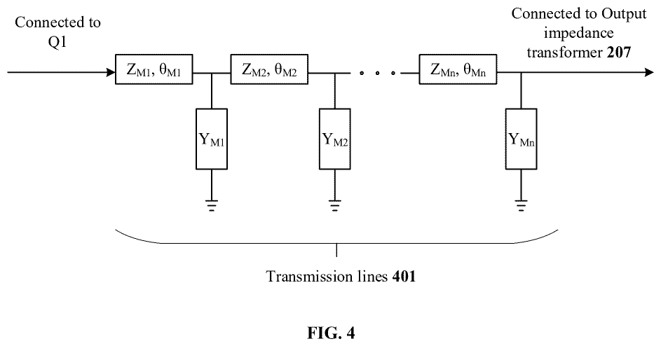

In an embodiment, the parasitic compensator & impedance inverter 203 helps in achieving a frequency agile impedance inversion for the operation of the DPA 200 over the wider bandwidth. In an implementation, the parasitic compensator & impedance inverter 203 may be designed based on the parasitic load of the transistor 1 Q1 110₁ connected to the main PA 103, an impedance provided by the output impedance transformer 207 and a quasi-open circuit impedance provided by the parasitic canceller 205, such that the parasitic compensator & impedance inverter 203 provides a required load modulation over a large variation in the input power for operation of the DPA 200 over a wider bandwidth. Further, the parasitic compensator & impedance inverter 203 may be configured with a plurality of sections, and each section of the plurality of sections may comprise a transmission line and a shunt admittance. The detailed internal architecture of the parasitic compensator & impedance inverter 203 is explained with reference to FIG. 4 of the present disclosure.

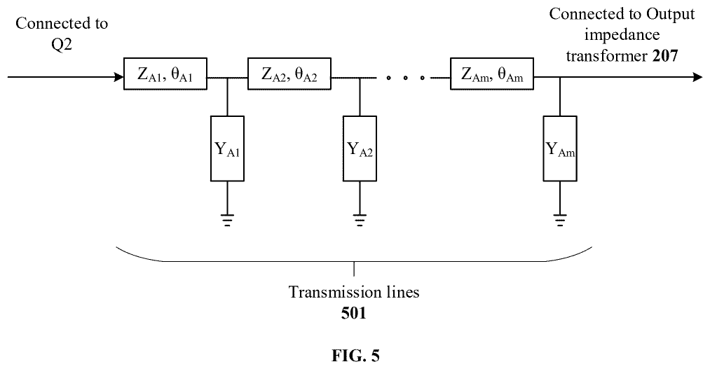

In an embodiment, the parasitic canceller 205 may be configured to provide a frequency agile parasitic cancellation for the DPA 200 while considering the effect of the parasitic load of the transistor 2 Q2 110₂ on the auxiliary PA 105. That is, the parasitic canceller 205 ensures both parasitic cancellation and modulation of an overall load on the DPA 200. In an implementation, the parasitic canceller 205 may be configured with a plurality of sections. Each section of the plurality of sections may comprise, without limitation, a transmission line and a shunt admittance. The detailed internal architecture of the parasitic canceller 205 is explained with reference to FIG. 5 of the present disclosure.

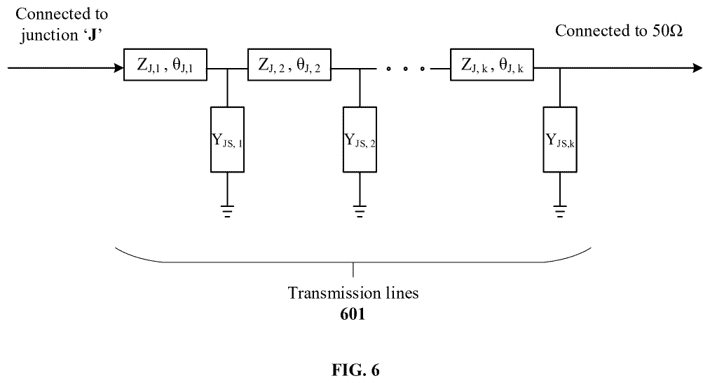

In an embodiment, the output impedance transformer 207 may be configured to provide an output impedance transformation of the load passing through a junction ‘J’ of the DPA 200, where the main PA 103 and the auxiliary PA 105 are connected. The detailed internal architecture of the impedance transformer 207 is explained with reference to FIG. 6 of the present disclosure.

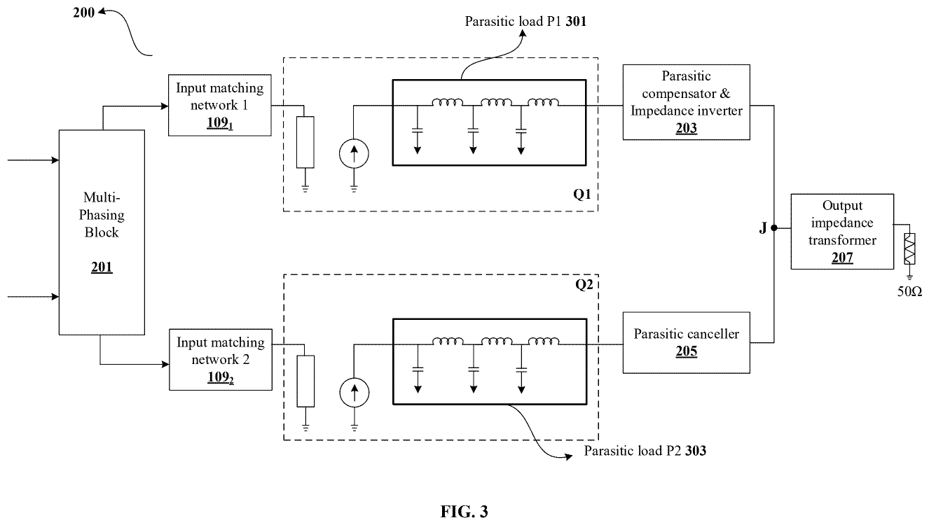

FIG. 3 illustrates a detailed architecture of the proposed DPA 200, in accordance with various embodiments of the present disclosure.

In an embodiment, FIG. 3 shows an equivalent circuit diagram of architecture of the proposed DPA 200, which is shown in FIG. 2. Particularly, in FIG. 3, the transistor Q1 110₁ and transistor Q2 110₂ are represented with their simplified equivalent circuits showing the parasitic load P1 301 and parasitic load P2 303, respectively.

In an emboidment, during operation of the DPA 200 at a low power level, the auxiliary PA 105 is maintained at an ‘OFF’ condition since the transistor Q2 110₂ is biased below its pinch-off value. Alternatively, the transistor Q1 110₁ in the main PA 103 is biased at the pinch-off or above the pinch-off value. Therefore, the main PA 103 starts operating even at the low power level, when the auxiliary PA 105 is in the ‘OFF’ condition. In such a case, the main PA 103 is terminated to a load, which is higher than its optimum value, thereby reaching a maximum voltage (i.e., voltage saturation) even at the low output current. In an embodiment, this required load may be provided by the parasitic compensator & impedance inverter 203, which is terminated with the parasitic canceller 205 and the output impedance transformer 207. Therefore, the parasitic compensator & impedance inverter 203 is designed with a prior knowledge of the parasitic load P1 301 and parasitic load P2 303, while considering an impedance value Z_{L} presented at the junction J and the parasitic canceller 205. The impedance value Z_{L} may be provided by the output impedance transformer 207. As an example, the impedance value Z_{L} may be 50Ω, as shown in FIG. 3.

In an embodiment, when the input power is at a certain back-off value, when the ouput voltage of the main PA 103 reaches to its peak value, the auxiliary PA 105 starts operating and gradually contributes to the output current. This output current will modify the load presented to the parasitic compensator & impedance inverter 203, which eventually ensures that the the load seen by the main PA 103 gradually reduces, as the input power drive increases. Therefore, the load seen by the main PA 103 reduces, whereas, the output current of the main PA 103 still increases. This ensures that the output voltage of the main PA 103 is maintained at its peak value from back-off phase to its saturation. Since the main PA 103 operates at voltage stauration (i.e., output voltage maintained at its peak value) even at the back-off power, it exhibits high efficiency operation.

In operation, the parasitic compensator & impedance inverter 203, along with the parasitic load P1 301 of the transistor Q1 110₁ of the main PA 103, ensures transformation of the transistor Q1 110₁ as a constant-voltage source at junction ‘J’. In an embodiment, the parasitic compensator & impedance inverter 203 may utilize the parasitic load P1 301 to achieve the desired output matching and impedance inversion to achieve the required frequency agile impedance inversion, and thereby extend the operation of the DPA 200 over the wide bandwidth. The network parameters of the parasitic compensator & impedance inverter 203 may be obtained while considering the parasitic load P1 301, parasitic load P2 303, the impedance Z_{L} presented at junction ‘J’. Therefore, in an implementation, the parasitic load P1 301, the parasitic compensator & impedance inverter 203, the parasitic canceller 205, the parasitic load P2 303 and the impedance Z_{L} may be considered as a three-port network, where the impedance Z_{L} is terminating the third port. In other words, the impedance Z_{L} may be realized by the output impedance transformer 207 when it is terminated by 50Q. Since the network parameters of the parasitic load P1 301 and the parasitic load P2 303 are known from the configuration of the transistor Q1 110₁ and transistor Q2 110₂ respectively, network parameters of the parasitic compensator & impedance inverter 203 and the parasitic canceller 205, along with the impedance Z_{L}, may be obtained by enforcing the optimum load conditions at the back-off and saturation power values.

In an embodiment, the optimum load condition may be determined based on standard operation of the DPA 200, where, at saturation, the optimum load is Rₒₚₜ and is obtained from the Current-Voltage (I/V) characteristics of the transistors. Thus, at back-off power, the main PA 103 should see the load Rₒₚₜ/β, where ‘β’ is a back-off factor. The back-off factor may be related to the average input power drive (back-off from saturation), where the efficiency needs to be improved in the operation of a typical DPA. For example, a 6 dB back-off may correspond to β=0.5, which results in 2 Rₒₚₜ load, which in turn terminates the main PA 103 at back-off power. However, due to the nonlinear current profile of the transistor Q2 110₂ with the input power, the load modulation presented by it results in a higher load seen by the main PA 103. This eventually exceeds the voltage swing over the maximum voltage rating of the transistor Q1 110₁, which eventually results in voltage clipping and increased nonlinearity. Therefore, the network parameter of the parasitic compensator & impedance inverter 203 are obtained by considering the load presented to the main PA 103, less than Rₒₚₜ/β at back-off. The network parameters of the parasitic compensator & impedance inverter 203 and the parasitic canceller 205 can be represented as Y, Z, ABCD or S-parameters. Once the network parameters of the parasitic compensator & impedance inverter 203 and parasitic canceller 205 are obtained, the network may be synthesized using the circuit topology.

In an embodiment, the parasitic compensator & impedance inverter 203 provides a frequency agile parasitic compensation and has the capability of wideband operation, because of its unique architecture, which is explained with reference to FIG. 4.

In an embodiment, the parasitic canceller 205, along with the parasitic load P2 303 of the auxiliary PA 105, ensures a constant current source at junction ‘J’, irrespective of the presence of the transistor device parasitic. The parasitic canceller 205 may also provide an output matching to the transistor Q2 110₂ to perform optimally. The parasitic canceller 205 is designed with a prior knowledge of the parasitic loads P1 301 of the transistors Q1 110₁, and parasitic load P2 303 associated with the transistor Q2 110₂. The network parameters of the parasitic canceller 205 may be obtained while considering the parasitic load P1 301 and parasitic load P2 303, the parasitic compensator & impedance inverter 203, and the impedance Z_{L} presented at the junction ‘J’ due to the output impedance transformer 207. The network parameters of the parasitic canceller 205 may be represented by S, Y, Z and ABCD parameters. These parameters may be obtained along with the network parameters of the parasitic compensator & impedance invertor, as described above. In summary, the network parameters of the whole circuit of the DPA 200 may be obtained simultaneously over the wide bandwidth, while considering their effect on each other and the effect of the impedance Z_{L} provided by the output impedance transformer 207. In an embodiment, the logic of obtaining the network parameters of the parasitic compensator & impedance inverter 203 and the parasitic canceller 205 with a prior knowledge of the parasitic load P1 301 and parasitic load P2 303, as described above, helps in solving the following two problems of the conventional DPA 100:
1. The matching networks can guarantee the Rₒₚₜ application since the load at junction ‘J’ changes dynamically with the input power drive due to the load modulation.
2. The slight leakage of the current from the main PA 103 to the auxiliary PA 105 may be minimized due to quasi-open circuit condition achieved by the parastic canceller, when the auxiliary PA 105 is in the ‘OFF’ condition at the low power operation. This is possible by designing the parasitic compensator & impedance inverter 203 in presence of the quasi-open circuit condition provided by the parastic canceller at junction J. This, in turn, enables the application of the appropriate loads to the transistors and thereby avoids clipping and enables linearity in the operation of the DPA 200.

In an embodiment, the parasitic canceller 205 ensures that there is no current leakage from the main PA 103 to the auxiliary PA 105 at the back-off power (i.e., when the Auxiliary PA 105 is OFF). Consequently, the parasitic canceller 205 ensures a frequency agile parasitic compensation of the transistor Q2 110₂ on the auxiliary PA 105. Also, the parasitic canceller 205 has the capability of wide band operation.

FIG. 4 illustrates an exemplary internal architecture of a parasitic compensator & impedance inverter 203 of the proposed DPA 200, in accordance with an embodiment of the present disclosure. In an implementation, the parasitic compensator & impedance inverter 203 may have a plurality of sections, each section comprising of, without limiting to, a transmission line 401 and a shunt admittance Y_{M1}, Y_{M2}, . . . , Y_{Mn}, as shown in FIG. 4. In an embodiment, the number of sections ‘n’ in the parasitic compensator & impedance inverter 203 and values of the components in each section may differ based on the frequency of operation, the optimum loads for different devices and different values of the corresponding parasitic loads. The transmission lines 401 may have a characteristic impedance value of Z_{M1}, Z_{M2}, Z_{M3}, . . . , Z_{Mn} corresponding to ‘n’ different sections. Similarly, the electrical length of the transmission lines 401 may be represented as θ_{M1}, θ_{M2}, θ_{M3}, . . . , θ_{Mn} corresponding to ‘n’ different sections. In an embodiment, the electrical lengths may independently take any values ranging from 0° to 360° for different values of the operating frequency. The characteristic impedances Z_{M1}, Z_{M2}, Z_{M3}, . . . , Z_{Mn} may also independently vary to any value from 10Ω to 300Ω.

In an embodiment, the shunt admittance Y_{M1}, Y_{M2}, Y_{M3}, . . . , Y_{Mn} corresponding to the ‘n’ different sections can have a ‘zero’ admittance value in some scenario. Alternatively, the values of the shunt admittances may be realized using an inductor, a capacitor or their series and shunt combinations in the circuit. The shunt admittance can also be realized using a transmission line stub, with a characteristic impedance that can take any value from 10Ω to 300Ω and electrical length that can take any value from 0° to 360° for different values of the operating frequency.

FIG. 5 illustrates an exemplary internal architecture of a parasitic canceller 205 of the proposed DPA 200, in accordance with an embodiment of the present disclosure. In an implementation, the parasitic canceller 205 may have a plurality of sections, each section comprising of, without limiting to, a transmission line 501 and a shunt admittance Y_{A1}, Y_{A2}, . . . , Y_{Am}, as shown in FIG. 5. In an embodiment, the number of sections ‘m’ in the parasitic canceller 205 and values of the components in each section may differ based on the frequency of operation, the optimum loads for different devices and different values of the corresponding parasitic loads. The transmission lines 501 may have a characteristic impedance value of Z_{A1}, Z_{A2}, Z_{A3}, . . . , Z_{Am} corresponding to ‘m’ different sections. Similarly, the electrical length of the transmission lines 501 may be represented as θ_{A1}, θ_{A2}, θ_{A3}, . . . , θ_{Am} corresponding to ‘m’ different sections. In an embodiment, the electrical lengths may independently take any values ranging from 0° to 360° for different values of the operating frequency. The characteristic impedances Z_{A1}, Z_{A2}, Z_{A3}, . . . , Z_{Am} may also independently vary to any value from 10Ω to 300Ω.

In an embodiment, the shunt admittance Y_{A1}, Y_{A2}, Y_{A3}, . . . , Y_{Am} corresponding to the ‘m’ different sections can have a ‘zero’ admittance value in some scenario. Alternatively, the values of the shunt admittances may be realized using an inductor, a capacitor or their series and shunt combinations in the circuit. The shunt admittance can also be realized using a transmission line stub, with a characteristic impedance that can take any value from 10Ω to 300Ω and electrical length that can take any value from 0° to 360° for different values of the operating frequency.

FIG. 6 illustrates an exemplary architecture of an output impedance transformer 207 of the proposed DPA 200, in accordance with an embodiment of the present disclosure. In an embodiment, the output impedance transformer 207 provides output impedance transformation for the DPA 200. The output impedance transformer 207 may comprise, without limiting to, a plurality of sections of transmission line 601 and a shunt admittance, as shown in FIG. 6. The characteristic impedances of the transmission lines 601 are represented by Z_{J,1}, Z_{J,2}, Z_{J,3}, . . . Z_{J,k}. The electrical length of the transmission lines 601 are represented by θ_{J,1}, θ_{J,2}, θ_{J,3}, . . . θ_{J,k}. The characteristic impedances Z_{J,1}, Z_{J,2}, Z_{J,3}, . . . Z_{J,k} may take values from 10Ω to 300Ω. The electrical length θ_{J,1}, θ_{J,2}, θ_{J,3}, . . . θ_{J,k} may take values from 0° to 360° at a particular frequency of operation. Similarly, shunt admittances Y_{JS,1}, Y_{JS,2}, Y_{JS,3}, . . . Y_{JS,k} may have ‘zero’ admittance value in some scenario. Alternatively, the shunt admittances may be of a definite, non-zero value, which will be realized using inductors, capacitors or their series and shunt combinations in the circuit.

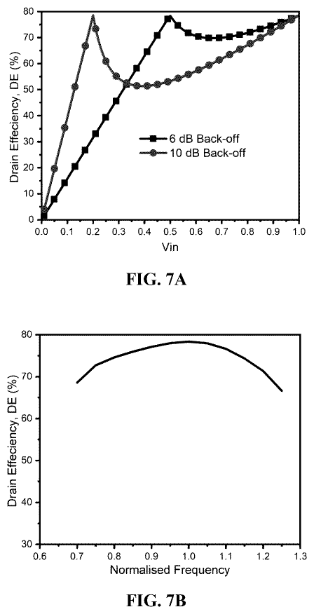

FIG. 7A illustrates the outcome of simulation of drain efficiency of the proposed DPA 200 with a normalized input voltage drive in accordance with embodiments of the present disclosure. In embodiment, the results in FIG. 7 indicate that the value of drain efficiency peaks for 6 dB and 10 dB of power back-off values, corresponding to the normalized input voltage (Vin) of 0.5V and 0.2V respectively.

FIG. 7B illustrates the outcome of simulation of drain efficiency in the proposed DPA 200 architecture with normalized frequency, in accordance with embodiments of the present disclosure. FIG. 7B particularly indicates the drain efficiency at an average power value of 6 dB back-off from the saturation value, with respect to the normalized frequency. It is evident that the efficiency remains at 10% of its maximum value over a fractional bandwidth of 51%. This means that the proposed DPA 200 shows a significant improvement over the conventional DPA 100, which has a fractional bandwidth of typically 15% in practice.

Advantages of the embodiments of the present disclosure are illustrated herein.

In an embodiment, the proposed DPA is configured to support a wideband performance with the use of a frequency agile parasitic compensator & impedance inverter.

In an embodiment, the proposed DPA is configured to provide an optimal performance over a wide bandwidth, while accommodating significant variations in input power drive and ensuring operational efficiency. Since the matching network and the parasitic compensator & impedance invertor are designed together as one unit, i.e., frequency agile parasitic compensator & impedance inverter, any changes in the load at a junction ‘J’, due to the load modulation, will not affect the required optimum load impedance Rₒₚₜ of the circuit.

In an embodiment, the proposed architecture enhances overall efficiency and performance of the DPA even when the DPA is operating at reduced power levels or in back-off scenarios. The proposed architecture for DPA also ensures that the amplifier remains effective across a wideband frequency operation, contributing to its flexibility and reliability in practical applications.

In an embodiment, the proposed architecture helps in avoiding clipping and ensures linearity in the operation of the DPA. The DPA will maintain a stable and linear performance even when faced with varying input signals and a wide frequency spectrum. In other words, the proposed architecture improves the bandwidth and linearity metric of the DPA.

In an embodiment, the proposed architecture helps to bridge the gap between theoretical expectations and real-world implementation of the DPAs and ensures that the performance of the DPA closely aligns with simulation results. This is possible since the parastic canceller is designed considering the effect of frequency agile impedance inverter and the impedance Z_{L} provided by the output impedance transformer.

In an embodiment, the proposed architecture improves the overall effectiveness of the power amplification systems with the use of the parasitic canceller.

In an embodiment, the proposed architecture helps in maintaining signal integrity and fidelity, making it suitable for applications where precise and undistorted signal amplification is crucial.

In an embodiment, the proposed DPA supports wideband operation modes on the power amplifier to achieve wide bandwidth extending to the octave range. The proposed DPA supports applying modified load modulation, which provides nonlinearity compensation for achieving good linearity at average power. As a result, the proposed DPA helps in mitigating the frequency dependence effects of the parasitic loads on the required load modulation, thereby enabling the wider frequency response.

In light of the technical advancements provided by the disclosed DPA architecture, the claimed architecture, as discussed above, is not routine, conventional, or well-known aspect in the art, as the claimed architecture provides the aforesaid solutions to the technical problems existing in the conventional PA architectures. Further, the claimed architecture clearly brings an improvement in the functioning of the DPA itself, as the claimed architecture provides a technical solution to a technical problem.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

Reference numerals:

| Reference | |
|---|---|
| numeral | Description |
| 100 | Structure of conventional Doherty Power Amplifier |
| | (DPA) |
| 101 | Input power splitter |
| 103 | Main Power Amplifier (PA) |
| 105 | Auxiliary PA |
| 107₁ | Input offset line on Main PA |
| 107₂ | Input offset line on Auxiliary PA |
| 109₁ | Input matching network on Main PA |
| 109₂ | Input matching network on Auxiliary PA |
| 110₁ | Transistor 1 (Q1) on Main PA |
| 110₂ | Transistor 2 (Q2) on Auxiliary PA |
| 111₁ | Output matching network on Main PA |
| 111₂ | Output matching network on Auxiliary PA |
| 113₁ | Quarter wave transformer on Main PA |
| 113₂ | Quarter wave transformer of the DPA |
| 115 | Phase-offset line |
| 200 | Structure of proposed DPA/wideband DPA |
| 201 | Multi-phasing block |
| 203 | Parasitic compensator & Impedance inverter |
| 205 | Parasitic canceller |
| 207 | Output impedance transformer |
| 301 | Parasitic load P1 on Main PA |
| 303 | Parasitic load P2 on Auxiliary PA |
| 401 | Transmission lines of Parasitic compensator & |
| | Impedance inverter |
| 501 | Transmission lines of Parasitic canceller |
| 601 | Transmission lines of Output impedance transformer |

What is claimed is:

1. A wideband Doherty Power Amplifier (DPA) circuit, the circuit comprising:
a main PA and an auxiliary PA;
an input power splitter configured to split an input power into the main PA and the auxiliary PA;
a multi-phasing block component to provide a phase difference between the main PA and the auxiliary PA;
a parasitic compensator & impedance inverter connected to the main PA to compensate a parasitic load P1 on the main PA and modulate an overall load on the DPA;
a parasitic canceller connected to the auxiliary PA to compensate the parasitic load P2 on the auxiliary PA and avoid leakage of current from the main PA to the auxiliary PA, when the auxiliary PA is in an ‘OFF’ state; and
an output impedance transformer connected to the main PA and the auxiliary PA.

2. The circuit of claim 1, wherein the parasitic compensator & impedance inverter is designed based on parasitic load P1 of transistor Q1 connected to the main PA, an impedance ZL provided by the output impedance transformer and a quasi-open circuit impedance provided by the parasitic canceller, such that the parasitic compensator & impedance inverter provides a required load modulation over a large variation in the input power and wide bandwidth, and
wherein the parasitic compensator & impedance inverter is configured with a plurality of sections, each section comprising a transmission line and a shunt admittance.

3. The circuit of claim 2, wherein number of sections in the parasitic compensator & impedance inverter is determined based on frequency of operation of the circuit, optimum load for the transistor and corresponding parasitic of the transistor.

4. The circuit of claim 1, wherein the parasitic canceller provides cancellation of the parasitic load P2 presented by a transistor Q2 in the auxiliary PA based on the parasitic load P1 presented by the transistor Q1 on the main PA, and wherein the parasitic canceller is configured with a plurality of sections, each section comprising a transmission line and a shunt admittance.

5. The circuit of claim 4, wherein number of sections in the parasitic canceller is determined based on frequency of operation of the circuit, optimum load for the transistor and corresponding parasitic loads P1, P2 of the transistors Q1, Q2, respectively.

6. The circuit of claim 2, wherein the transmission line on each of the plurality of sections has a characteristic impedance corresponding to each of the plurality of sections.

7. The circuit of claim 2, wherein an admittance value of the shunt admittance is realized using at least one inductor in the circuit, at least one capacitor in the circuit, a series combination of the at least one inductor and the at least one capacitor or a shunt combination of the at least one inductor and the at least one capacitor.

8. The circuit of claim 2, wherein the admittance value of the shunt admittance is realized using a transmission line stub with a predefined characteristic impedance value.

9. The circuit of claim 1, wherein the multi-phasing block component is configured with a combination of delay lines to provide multiple phase shifts corresponding to different values of a frequency of operation to compensate a phase difference between the main PA and the auxiliary PA.

10. The circuit of claim 1, wherein operation of the auxiliary PA is triggered when an output voltage of the main PA is more than a predefined peak voltage.

11. The circuit of claim 10, wherein an output current generated during the operation of the auxiliary PA causes modulation of the load on the main PA such that the load on the main PA reduces with increase in the input power.

12. The circuit of claim 1, wherein each of the main PA and the auxiliary PA further comprise an input matching network.

13. The circuit of claim 1, wherein each of the main PA and the auxiliary PA further comprise a broadband input power divider.

14. The circuit of claim 1, wherein network parameters of the circuit are obtained simultaneously over the wide bandwidth, while considering their effect on each other and the effect of load impedance ZL provided by the output impedance transformer.

15. The circuit of claim 1, wherein the circuit is configured to modify the load to the transistor in the main PA over a wide input drive and wide bandwidth while avoiding clipping and corresponding addition of nonlinearity in operation of the DPA.
